(19) United States
(12) Patent Application Publication
(10) Pub. No.: US 2008/0129371 A1
(43) Pub. Date: Jun. 5, 2008

(54) SEMICONDUCTOR DEVICE AND TRIMMING METHOD

(75) Inventors: Udo Hartmann, Neuried (DE); Patric Stracke, Munchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Qimonda AG, Muenchen (DE)

(21) Appl. No.: 11/947,882

(22) Filed: Nov. 30, 2007

(30) Foreign Application Priority Data
Nov. 30, 2006 (DE) 10 2006 056 560.0

(51) Int. Cl. H03K 3/45; H01L 21/66

(52) U.S. Cl. 327/513; 438/10; 257/E21.526

(57) ABSTRACT

A device and method for determining target values for a parameter of a semiconductor device to be trimmed. A first target value is determined for a parameter to be trimmed for a first temperature, and a second target value differing from the first target value is determined for the parameter to be trimmed for a second temperature differing from the first temperature

### CROSS-REFERENCE TO RELATED APPLICATIONS

This Utility Patent Application claims the benefit of German Application DE 10 2006 056 560.6, filed Nov. 30, 2006 incorporated herein by reference.

### BACKGROUND

Semiconductor devices, e.g. corresponding, integrated (analog or digital) computing circuits, semiconductor memory devices such as, for instance, functional memory devices (PLAs, PALs, etc.) and table memory devices (e.g. ROMs or RAMs, in particular SRAMs and DRAMs), etc. are subject to comprehensive tests during and after their manufacturing process.

For the common manufacturing of a plurality of (in general identical) semiconductor devices, a wafer (i.e. a thin disc of monocrystalline silicon) is used. The wafer is processed appropriately (e.g. subject successively to a plurality of coating, exposure, etching, diffusion, and implantation process steps, etc.), and subsequently e.g. sawn apart (or e.g. scratched, and broken), so that the individual devices are then available.

During the manufacturing of semiconductor devices such as DRAMS (Dynamic Random Access Memories or dynamic read-write memories), in particular DDR-DRAMs (Double Data Rate-DRAMs)—even before all the desired, above-mentioned processing steps were performed on the wafer—(i.e. already in a semi-finished state of the semiconductor devices) the (semi-finished) devices (that are still available on the wafer) may be subject to appropriate tests at one or a plurality of test stations by one or a plurality of test devices (e.g. kerf measurements at the wafer kerf).

After the finishing of the semiconductor devices (i.e. after the performing of all the above-mentioned wafer processing steps), the semiconductor devices are subject to further tests at one or a plurality of (further) test stations—for instance, by appropriate (further) test devices, the finished devices—that are still available on the wafer—may be tested appropriately (“wafer tests”).

Correspondingly, one or a plurality of further tests (at corresponding further test stations, and by using appropriate, further test devices) may be performed, for instance, after the incorporation of the semiconductor devices in the corresponding semiconductor device packages, and/or e.g. after the incorporation of the semiconductor device packages (along with the respectively included semiconductor devices) in corresponding electronic modules, e.g. memory modules (“module tests”).

Based on the results of the above-mentioned tests it is possible to perform appropriate parameter settings with the above-mentioned semiconductor devices.

For instance, reference voltages and/or reference currents may be trimmed such that they correspond as exactly as possible to respectively predetermined target values.

When trimming or setting the parameters, e.g. the above-mentioned reference voltages and/or reference currents, appropriate laser fuse methods (and/or e.g. appropriate electric fuse methods, etc.) may, for instance, be used.

By using appropriate laser fuse methods, for instance—depending on the above-mentioned test results—a number of resistors that differs from semiconductor device to semiconductor device may be placed in an “activated” state (i.e. be used later during the regular operation of a semiconductor device for generating a voltage/a current), or in a “deactivated” state (i.e. not be used later during the regular operation of a semiconductor device for generating a voltage/a current).

Thus, it is, for instance, possible to influence the (total) resistance achieved by the resistors altogether, and hence, for instance, the voltage drop caused by them (and/or the current flowing through them, etc.), and thus e.g. the value of corresponding reference voltages and/or reference currents used on the semiconductor device, etc.

Semiconductor devices have to operate faultlessly in a predetermined range of operating temperature.

The above-mentioned parameters, e.g. corresponding reference voltages and/or reference currents, therefore have to be trimmed such that a faultless operation is ensured even with extreme temperatures—at the upper and lower margins of the range of operating temperature.

For this reason, semiconductor devices are conventionally trimmed such that a corresponding “safety margin” or a corresponding “allowance”, respectively, results for “normal” or “average” temperatures.

If a semiconductor device does not fulfil the respective requirements over the entire, respectively desired range of operating temperature, the semiconductor device has to be sold with a markdown or—in the worst case—has to be thrown away.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1a is a schematic representation of stations that are run through during the manufacturing of corresponding semiconductor devices, and of a plurality of test devices used for testing the semiconductor devices;

FIG. 1b is a schematic representation of further stations that are run through during the manufacturing of corresponding semiconductor devices, and of several further test devices used for testing the semiconductor devices;

FIG. 2 is an exemplary schematic representation of a semiconductor device in accordance with an embodiment of the invention;

FIG. 3 is an exemplary diagram for illustrating an interpolation method that can be used in accordance with an embodiment of the invention for ascertaining a trimming to be used; and

FIG. 4 is an exemplary diagram for illustrating a further interpolation method that can be used in accordance with a further embodiment of the invention for ascertaining a trimming to be used.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

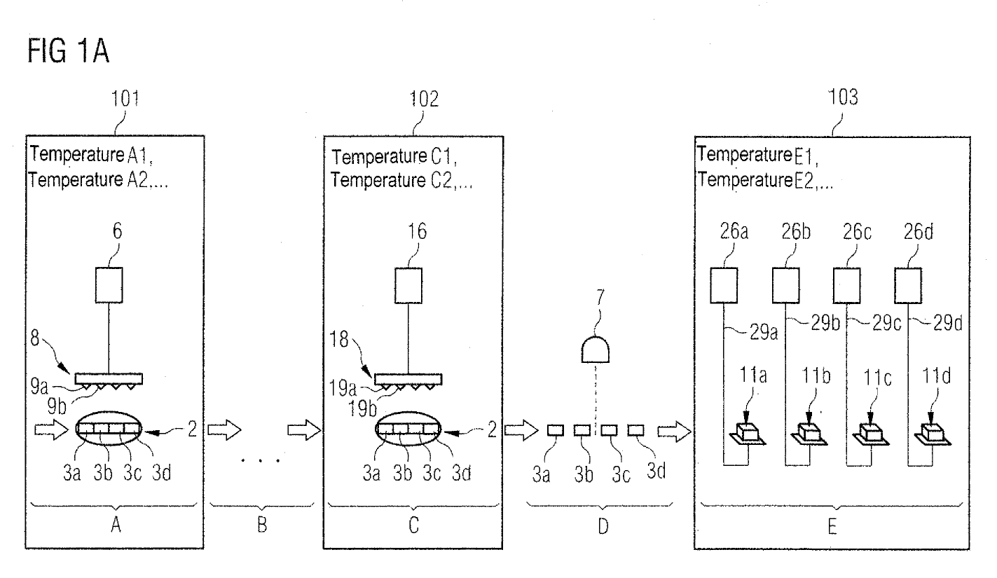

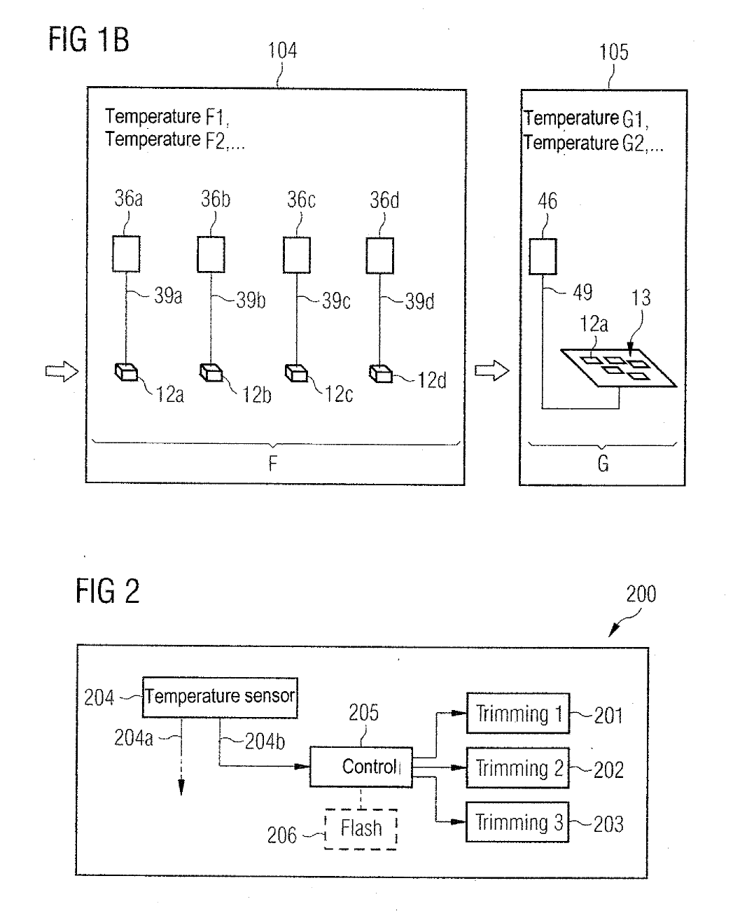

FIGS. 1a and 1b schematically illustrate some (out of a plurality of further, not illustrated) stations A, B, C, D, E, F, G that are run through by corresponding semiconductor devices 3a, 3b, 3c, 3d during the manufacturing of semiconductor devices 3a, 3b, 3c, 3d.

The semiconductor devices 3a, 3b, 3c, 3d may, for instance, be corresponding, integrated (analog or digital) computing circuits, and/or semiconductor memory devices such as functional memory devices (PLAs, PALs, etc.) or table memory devices (ROMs or RAMS, etc.), in particular SRAMs, DRAMs, DDR-DRAMs (Double Data Rate-DRAMs), high-speed DDR-DRAMs, etc.

During the manufacturing of the semiconductor devices 3a, 3b, 3c, 3d, an appropriate silicon disc or an appropriate wafer 2 is located at stations that are positioned upstream or downstream of the station A illustrated in FIG. 1a (e.g. at the station B that is positioned downstream of the station A, and at a plurality of further, not illustrated stations (that are positioned upstream or downstream of the station A)—subject to corresponding, conventional coating, exposure, etching, diffusion, and/or implantation process steps, etc.

The station A serves to subject the semiconductor devices 3a, 3b, 3c, 3d—which are still available on the wafer 2—to one or a plurality of test methods—e.g. kerf measurements at the wafer kerf—by a test device 6 (namely—as results from the above statements—even before all the desired, above-mentioned processing steps were performed at the wafer 2 (i.e. already in a semi-finished state of the semiconductor devices 3a, 3b, 3c, 3d).

The voltages/currents or test signals required at the station A for testing the semiconductor devices 3a, 3b, 3c, 3d on the wafer 2 are generated by the test device 6 and are applied to corresponding connections of the semiconductor devices 3a, 3b, 3c, 3d by a semiconductor device test card 8 or probe card 8 (more particularly: by corresponding contact needles 9a, 9b provided at the probe card 8) which is connected with the test device 6.

From the station A, the wafer 2 is (typically in a fully automated manner) transported forward to the station B (and from there possibly to a plurality of further—not illustrated—stations) where—as was already mentioned above—the wafer 2 is subject to appropriate, further processing steps (in particular appropriate coating, exposure, etching, diffusion, and/or implantation process steps, etc.), and/or—correspondingly similar as at the station A—to corresponding further test methods.

After the finishing of the semiconductor devices (i.e. after the performing of all the above-mentioned wafer processing steps) the wafer 2 is, from the corresponding—last—processing station (e.g. the station B or the further stations positioned downstream thereof)—transported forward to the next station C—typically in a fully automated manner.

The station C serves to subject the finished semiconductor devices 3a, 3b, 3c, 3d—that are still available on the wafer 2- to one or a plurality of—further—test methods by a test device 16 (e.g. wafer tests).

The voltages/currents or test signals required at the station C for testing the semiconductor devices 3a, 3b, 3c, 3d on the wafer 2 are generated by the test device 16 and are applied to corresponding connections of the semiconductor devices 3a, 3b, 3c, 3d by a semiconductor device test card 18 or probe card 18 (more particularly: by corresponding contact needles 19a, 19b that are provided at the probe card 18) which is connected with the test device 16.

From the station C, the wafer 2 is (typically in a fully automated manner) transported forward to the next station D, and is there (after the wafer 2 was laminated with a film in a per se known manner) sawn apart (or e.g. scratched, and broken) by using an appropriate machine 7, so that the semiconductor devices 3a, 3b, 3c, 3d are then available individually (as corresponding semiconductor device chips).

Prior to being transported forward to the station D, the wafer 2—or the devices 3a, 3b, 3c, 3d available thereon—may be subject to one or a plurality of further test methods at one or a plurality of stations corresponding to the station C.

After the sawing apart of the wafer 2 at the station D, every single device or every single chip 3a, 3b, 3c, 3d is then (typically in a fully automated manner) loaded into an appropriate carrier 11a, 11b, 11c, 11d or an appropriate outer package, and the semiconductor devices 3a, 3b, 3c, 3d—that are loaded into the carriers 11a, 11b, 11c, 11d—are subject to one or a plurality of further test methods (e.g. carrier tests) at one or a plurality of (further) test stations—e.g. the station E illustrated in FIG. 1a.

To this end, the carriers 11a, 11b, 11c, 11d are introduced into corresponding carrier sockets or carrier adapters, respectively, which are connected with one (or a plurality of) corresponding test device(s) 26a, 26b, 26c, 26d via corresponding lines 29a, 29b, 29c, 29d.

The voltages/currents or test signals required at the station E for testing the semiconductor devices 3a, 3b, 3c, 3d in the carriers 11a, 11b, 11c, 11d are generated by the test device(s) 26a, 26b, 26c, 26d and applied to corresponding connections of the semiconductor devices 3a, 3b, 3c, 3d via the carrier sockets that are connected with the test device(s) 26a, 26b, 26c, 26d via the lines 29a, 29b, 29c, 29d, and the carriers 11a, 11b, 11c, 11d that are connected thereto.

From the station E, the semiconductor devices 3a, 3b, 3c, 3d are (typically in a fully automated manner) transported forward to one or a plurality of—not illustrated—station(s) where the semiconductor devices 3a, 3b, 3c, 3d are incorporated into appropriate packages 12a, 12b, 12c, 12d (e.g. appropriate plug or surface-mountable device packages, etc.).

As is illustrated in FIG. 1b, the semiconductor devices 3a, 3b, 3c, 3d—that are mounted into the packages 12a, 12b, 12c, 12d—are then transported forward to one (or a plurality of) further test station(s)—e.g. the station F illustrated in FIG. 1b—, and are subject to one or a plurality of further test methods there.

To this end, the semiconductor device packages 12a, 12b, 12c, 12d are introduced into appropriate device package sockets or device package adapters which are—via corresponding lines 39a, 39b, 39c, 39d—connected with one (or a plurality of) corresponding test device(s) 36a, 36b, 36c, 36d.

The voltages/currents or test signals required at the station F for testing the semiconductor devices 3a, 3b, 3c, 3d—that are incorporated in the packages 12a, 12b, 12c, 12d—are generated by the test device(s) 36a, 36b, 36c, 36d and are applied to corresponding connections of the semiconductor devices 3a, 3b, 3c, 3d via the package sockets that are, via the lines 39a, 39b, 39c, 39d, connected with the test device(s) 36a, 36b, 36c, 36d and the device packages 12a, 12b, 12c, 12d that are connected thereto.

From the station F, the semiconductor devices 3a, 3b, 3c, 3d incorporated in the packages 12a, 12b, 12c, 12d may then—optionally—be transported forward to one or a plurality of—not illustrated—further station(s), where a corresponding semiconductor device package (e.g. the package 12a together with the semiconductor 3a incorporated therein) is—along with further devices (analog or digital computing circuits, and/or semiconductor memory devices, e.g. PLAs, PALs, ROMs, RAMS, in particular SRAMs or DRAMs, etc.)—connected to a corresponding electronic module 13—e.g. a printed circuit board.

As is illustrated in FIG. 1b, the electronic module 13 (and thus also the semiconductor devices 3a that are connected to the electronic module 13 (and are incorporated in a corresponding package 12a) may then—optionally—be transported forward to one (or a plurality of) further test stations—e.g. the station G illustrated in FIG. 1b—, and be subject there to one or a plurality of further test methods (in particular module tests).

The voltages/currents or test signals required at the station G for testing the module 13 (and thus the semiconductor devices 3a incorporated therein) are, for instance, generated by a test device 46 and are applied, via a line 49, to the electronic module 13 and thus to the corresponding connections of the corresponding semiconductor devices 3a that are incorporated therein.

As is schematically illustrated in FIGS. 1a and 1b, one or a plurality of the above-mentioned test methods that are performed at the test stations A, and/or C, and/or E, and/or F, and/or G, etc. may be performed in appropriate, sealed test rooms or test environments 101, 102, 103, 104, 105, and at several different, predetermined temperatures each.

For instance, at the test station A, a test method with the semiconductor devices 3a, 3b, 3c, 3d may initially be performed at a first temperature A1 (and then, for instance, with further, not illustrated semiconductor devices again at the first temperature A1, etc., etc.), and subsequently an identical test method at a second temperature A2 that differs from the first temperature A1 (again with the semiconductor devices 3a, 3b, 3c, 3d, and/or (additionally) with the further, not illustrated semiconductor devices, etc.).

Optionally, an identical test method may then—again—be performed at the test station A at a third temperature A3 that differs from the first and second temperatures (again with the semiconductor devices 3a, 3b, 3c, 3d, and/or (additionally) with the further, not illustrated semiconductor devices, etc.), etc., etc.

Correspondingly similar, also at the test station C (and/or at the test stations E, and/or F, and/or G, etc.), a test method with the semiconductor devices 3a, 3b, 3c, 3d may initially be performed at a temperature C1 (or E1, F1, G1, . . . ) (and then, for instance, with further, not illustrated semiconductor devices, again at the first temperature C1, etc., etc.), and subsequently an identical test method at a second temperature C2 (or E2, F2, G2, . . . ) that differs from the first temperature (again with the semiconductor devices 3a, 3b, 3c, 3d, and/or (additionally) with the further, not illustrated semiconductor devices, etc.), etc., etc.

The temperature A1 may, for instance, be substantially identical to the above-mentioned temperature C1 (or E1, F1, G1, . . . ), and the temperature A2, for instance, substantially identical to the above-mentioned temperature C2 (or E2, F2, G2, . . . ), or alternatively—different therefrom.

Based on the results of the above-mentioned test methods (or on the results of a part of the above-mentioned test methods), appropriate target values for parameters—e.g. appropriate reference voltages and/or reference currents—may be determined for future semiconductor devices to be manufactured (e.g. such that the semiconductor devices operate “optimally” with the predetermined parameter target values, e.g. with respect to reliability, and/or rate, and/or power consumption, etc.).

Based on the results of the above-mentioned test methods (or on the results of a part of the above-mentioned test methods), for different temperatures respectively different target values for parameters for future semiconductor devices to be manufactured may be determined.

For instance, based on the results of the above-mentioned test methods, a first parameter target value set may be determined for the above-mentioned first temperature A1 (or C1, E1, . . . ), or for a first temperature range assigned to this temperature, such that the semiconductor devices operate “optimally” with the predetermined first parameter target value set at the above-mentioned first temperature A1/in the above-mentioned first temperature range, e.g. with respect to reliability, and/or rate, and/or power consumption, etc.

Additionally, based on the results of the above-mentioned test methods, a second parameter target value set may be determined for the above-mentioned second temperature A2 (or C2, E2, . . . ), or for a second temperature range assigned to this temperature, such that the semiconductor devices operate “optimally” with the predetermined second parameter target value set at the above-mentioned second temperature A2, or in the above-mentioned second temperature range, e.g. with respect to reliability, and/or rate, and/or power consumption, etc.

Alternatively, based on the results of the above-mentioned test methods, a third parameter target value set may additionally be determined for the above-mentioned third temperature A3, or for a third temperature range assigned to this temperature, such that the semiconductor devices operate “optimally” with the predetermined third parameter target value set at the above-mentioned third temperature A3, or in the above-mentioned third temperature range, and a fourth (and possibly fifth) parameter target value set may be determined additionally on the basis of the results of the above-mentioned test methods for a fourth (and possibly fifth, etc.) temperature, or temperature range assigned to this temperature, etc.

The parameter target values or parameter target value sets predetermined in the above-mentioned manner may—as will be explained in more detail in the following—be used for the trimming of future semiconductor devices to be manufactured.

The entire range of operating temperature predetermined for the semiconductor devices is covered with the above-mentioned first, second (and possibly third, etc.) temperature ranges altogether.

The predetermined range of operating temperature may, for instance, lie between −10° C. and 85° C., with the first temperature range assigned to the above-mentioned first temperature A1 between 10° C. and 20° C., the second temperature range assigned to the above-mentioned second temperature A2 between 20° C. and 50° C., and the third temperature range assigned to the above-mentioned third temperature A3 between 50° C. and 85° C., etc.

The above-mentioned temperatures assigned to the temperature ranges may, for instance, each lie substantially in the middle of the respective temperature range.

Based on the results of the above-mentioned test methods (or on the results of a part of the above-mentioned test methods)—the above-mentioned parameter target values are first of all determined coarsely or preliminarily only in the above-mentioned manner.

Subsequently, with corresponding semiconductor devices that are to be manufactured newly or have been manufactured newly, the corresponding parameters are trimmed to the above-mentioned coarse target values in the manner that will be explained in more detail below.

Next, one or a plurality of the above-mentioned test methods (e.g. the above-mentioned test method performed at the station A, and/or C, and/or E, and/or F, and/or G, etc.), and/or one or a plurality of further test methods are performed (again) with the semiconductor devices that are to be manufactured newly or have been manufactured newly, with a corresponding parameter coarse setting of the semiconductor devices that are to be manufactured newly or have been manufactured newly.

The test methods may again be repeated several times at a plurality of different, predetermined temperatures (e.g. initially at the above-mentioned first temperature A1 (or C1, E1, F1, G1, . . . ), then at the above-mentioned second temperature A2 (or C2, E2, F2, G2, . . . ), and possibly at the above-mentioned third (and fourth, etc.) temperature A3 (or C3, E3, F3, G3, . . . ), etc.).

Based on the results of the above-mentioned test methods (or on the results of a part of the above-mentioned test methods), for future semiconductor devices to be manufactured, the above-mentioned parameter target values—or the parameter target value sets that are different for different temperatures—may then be determined finer or more exactly than this was the case before (e.g. such that the semiconductor devices operate even “more optimally” with the parameter target values or parameter target value sets which have been determined finer or more exactly, e.g. with respect to reliability, and/or rate, and/or power consumption, etc.).

Subsequently, with corresponding further semiconductor devices that are to be manufactured newly or have been manufactured newly, the corresponding parameters may, in the manner that will be explained in more detail below, be trimmed to the above-mentioned target values that have been determined finer or more exactly.

Next, one or a plurality of the above-mentioned test methods (e.g. the above-mentioned test method performed at the station A, and/or C, and/or E, and/or F, and/or G, etc.), and/or one or a plurality of further test methods may be performed (again) with the further semiconductor devices that have to be manufactured newly or have been manufactured newly, with a corresponding parameter setting of the semiconductor devices.

Based on the results of the above-mentioned test methods (or on the results of a part of the above-mentioned test methods), for future semiconductor devices to be manufactured, the above-mentioned parameter target values—or the parameter target value sets that are different for different temperatures—may then be determined even finer or more exactly than this was the case before, etc., until the final parameter target values or parameter target value sets that are to be used for the actual (mass) production of semiconductor devices have been found or have been determined, respectively (or the parameter target values or parameter target value sets used for trimming during the actual mass production of semiconductor devices).

In the above-mentioned manner it may, for instance, be ascertained or determined that, for the first temperature range that is assigned to the above-mentioned first temperature A1 (e.g. between −10° C. and 20° C.), the value of a first parameter, e.g. of a first reference voltage #1 is, for instance, to be trimmed to a parameter target value of e.g. 1.00 V, the value of a second parameter, e.g. of a second reference voltage #2, to a parameter target value of, for instance, 2.5 V, and the value of a third parameter, e.g. of a reference current #1, for instance, to a parameter target value of e.g. 10 μA, etc.

Furthermore, in the above-mentioned manner it may, for instance, be ascertained or determined that, for the second temperature range that is assigned to the above-mentioned second temperature A2 (e.g. between 20° C. and 50° C.), the value of the first parameter, e.g. of the first reference voltage #1, is, for instance, to be trimmed to a parameter target value of e.g. 1.05 V, the value of the second parameter, e.g. of the second reference voltage #2, for instance, to a parameter target value of e.g. 2.4 V, and the value of the third parameter, e.g. of the reference current #1, for instance, to a parameter target value of e.g. 12 μA, etc.

Moreover, in the above-mentioned manner, it may, for instance, be ascertained or determined that, for the third temperature range that is assigned to the above-mentioned third temperature A3 (e.g. between 50° C. and 85° C.), the value of the first reference voltage #1 is, for instance, to be trimmed to a parameter target value of e.g. 1.10 V, the value of the second reference voltage #2, for instance, to a parameter target value of e.g. 2.3 V, and the value of the reference current #1, for instance, to a parameter target value of e.g. 16 μA, etc.

As will be explained in more detail in the following, the above-mentioned parameters or parameter sets—e.g. the above-mentioned or further reference voltages and/or reference currents, etc. used on the semiconductor devices—are, during the trimming of the semiconductor devices, trimmed such that they correspond as exactly as possible to the respective target values/target value sets that have been determined in the above-mentioned manner.

As has already been explained above, in the present embodiment respectively different parameter target value sets are used for respectively different temperatures or temperature ranges, and thus correspondingly also respectively different trimmings 201, 202, 203 for respectively different temperatures or temperature ranges (cf also the semiconductor device 200 illustrated by way of example in FIG. 2).

During the trimming or setting of the parameters, e.g. of the above-mentioned reference voltages and/or reference currents, appropriate laser fuse methods (and/or, for instance, appropriate electrical fuse methods, etc.) may, for instance, be used correspondingly similar as conventionally.

By using appropriate laser fuse methods, for instance, a number of resistors that differ from semiconductor device to semiconductor device, and for each of the above-mentioned temperatures or temperature ranges, may be placed in an “activated” state (i.e. be used later during the regular operation of a semiconductor device for generating a voltage/a current), or in a “deactivated” state (i.e. not be used later during the regular operation of a semiconductor device for generating a voltage/a current).

On a corresponding semiconductor device 200, for instance—for setting a particular, first parameter—a first set of resistors (“trimming 1”) may be provided for the above-mentioned first temperature range, a second set of transistors (“trimming 2”) for the above-mentioned second temperature range, and a third set of transistors (“trimming 3”) for the above-mentioned third temperature range, etc. (wherein the resistors of one trimming and/or of all trimmings may, for instance, be of substantially equal size).

By using appropriate laser fuse methods, in the semiconductor device 200, for instance, for the above-mentioned first temperature range that is assigned to the above-mentioned first temperature A1 (e.g. between −10° C. and 20° C.), a first number of resistors of the first set of resistors may be placed in an “activated” state (i.e. be used later during the regular operation of the semiconductor device for generating a voltage/a current), or in a “deactivated” state (i.e. not be used later during the regular operation of the semiconductor device for generating a voltage/a current).

Furthermore, by using appropriate laser fuse methods, in the semiconductor device 200, for instance, for the above-mentioned second temperature range that is assigned to the above-mentioned second temperature A2 (e.g. between 20° C. and 50° C.) a second, different number of resistors of the second set of resistors may be placed in an “activated” state (i.e. be used later during the regular operation of a semiconductor device for generating a voltage/a current), or in a “deactivated” state (i.e. not be used later during the regular operation of a semiconductor device for generating a voltage/a current).

Moreover, by using appropriate laser fuse methods, in the semiconductor device 200, for instance, for the above-mentioned third temperature range—that is assigned to the above-mentioned third temperature A3 (e.g. between 50° C. and 85° C.), a third number of resistors of the third set of resistors which differs from the first and second numbers may be placed in an “activated” state (i.e. be used later during the regular operation of a semiconductor device for generating a voltage/a current), or in a “deactivated” state (i.e. not be used later during the regular operation of a semiconductor device for generating a voltage/a current).

As results from FIG. 2, and as will be explained in more detail in the following, a trimming selection control 205 and, for measuring the temperature, a temperature sensor 204 are provided on the semiconductor device 200.

The temperature sensor 204 may as described in more detail below, be used for one or a plurality of further purposes.

For instance, if the semiconductor device 200 is a DRAM, a refresh has to be performed regularly. The frequency of performing a refresh may be made dependent on the temperature measured by the temperature sensor 204, or on temperature measurement data that are provided by the temperature sensor 204 e.g. at a line 204a.

As results further from FIG. 2, the temperature measured by the temperature sensor 204 (or the corresponding temperature measurement data) may be provided to the above-mentioned trimming selection control means 205 via a line 204b.

Depending on the respectively measured temperature, the trimming selection control 205 then initiates that the trimming 201, 202, 203 assigned to the respectively measured temperature or to the determined temperature range is used during operation of the semiconductor device 200 (e.g. in that the respectively assigned trimming 201 is placed in an “activated” state and the remaining trimmings 202, 203 are placed in a “deactivated” state).

If, for instance, by the trimming selection control means 205, it is ascertained that the temperature measured by the temperature sensor 204 lies in the above-mentioned first temperature range (e.g. between −10° C. and 20° C.), the above-mentioned “trimming 1” may, for instance, be activated and the remaining trimmings (“trimming 2”, “trimming 3”) may be deactivated, so that the above-mentioned first number of resistors (of the first set of resistors) that are “activated” in this manner are used during the generation of a corresponding reference voltage/reference current.

The corresponding reference voltage/the corresponding reference current will then assume the value of the target value desired for the above-mentioned first temperature range (e.g. the above-mentioned first reference voltage #1 the value 1.00 V).

If, however, the trimming selection control 205 ascertains, for instance, that the temperature measured by the temperature sensor 204 lies in the above-mentioned second temperature range (e.g. between 20° C. and 50° C.), the above-mentioned “trimming 2” may, for instance, be activated, and the remaining trimmings (“trimming 1”, trimming 3”) may be deactivated, so that the above-mentioned second number of resistors (of the second set of resistors) that are “activated” in this manner are used during the generation of the corresponding reference voltage/reference current.

The corresponding reference voltage/the corresponding reference current will then assume the value of the target value desired for the above-mentioned second temperature range (e.g. the above-mentioned first reference voltage #1 the value 1.05 V).

Correspondingly, if the trimming selection control 205, for instance, ascertains that the temperature measured by the temperature sensor 204 lies in the above-mentioned third temperature range (e.g. between 50° C. and 85° C.), the above-mentioned “trimming 3” may, for instance, be activated, and the remaining trimmings (“trimming 1”, trimming 2”) may be deactivated, so that the above-mentioned third number of resistors (of the third set of resistors) that are “activated” in this manner are used during the generation of the corresponding reference voltage/reference current.

The corresponding reference voltage/the corresponding reference current will then assume the value of the target value desired for the above-mentioned third temperature range (e.g. the above-mentioned first reference voltage #1 the value 1.10 V).

Alternatively, instead of the above-mentioned plurality of sets of resistors, only one single set of resistors may be used for generating a corresponding reference voltage/reference current, and a respectively different number of resistors of the set of resistors may, depending on the respectively ascertained temperature range, be placed in an “activated” state (i.e. be used later during the regular operation of the semiconductor device for generating a voltage/a current), or in a “deactivated” state (i.e. not be used later during the regular operation of a semiconductor device for generating a voltage/a current)—e.g. by a corresponding, variable, bridging or non-bridging of the corresponding resistors by the trimming selector control means 205.

The corresponding reference voltage/the corresponding reference current will then, again, assume the target value that is respectively predetermined for the respective temperature range.

The corresponding trimming setting—e.g. the number of resistors that are respectively to be activated or to be deactivated for the respective temperature ranges—may be stored in a look-up table that is, for instance, stored on the semiconductor device 200, which is correspondingly accessed by the trimming selection control means 205.

To this end, a corresponding non-volatile memory, such as a corresponding flash memory 206, may be provided on the semiconductor device 200 (illustrated in dashes in FIG. 2).

For trimming the semiconductor device 200, one or a plurality of the above-mentioned test methods (e.g. the above-mentioned test method performed at the station A, and/or C, and/or E, and/or F, and/or G, etc.), and/or one or a plurality of further test methods may be performed therewith, in fact several times, at respectively different temperatures (in particular, for instance, at the above-mentioned temperature A1, or in the (first) temperature range assigned to this temperature, at the above-mentioned temperature A2, or the (second) temperature range assigned to this temperature, the above-mentioned temperature A3, or the temperature range assigned to this temperature, etc., etc.).

Based on the results of the above-mentioned test methods, in the semiconductor device 200, the above-mentioned parameters or parameter sets—e.g. the above-mentioned or further reference voltages and/or reference currents used on the semiconductor device, etc.—are (in particular in the above-explained manner) trimmed such that they correspond as exactly as possible to the respective target values/target value sets determined in the above-mentioned manner.

The above-mentioned trimming setting ascertained during the trimming of the semiconductor device 200—e.g. the number of resistors to be activated or to be deactivated for the respective temperature ranges—, or the above-mentioned look-up table, respectively, may, instead on the above-mentioned (internal) flash memory 206, e.g. also be stored on a memory that is arranged externally of the semiconductor device 200, for instance, an appropriate, separate chip.

The external memory may, via appropriate pads or pins, be connected with corresponding pads or pins of the semiconductor device 200, and this way with the trimming selection control 205 of the semiconductor device 200, so that the trimming selection control 205 is adapted to correspondingly access the trimming setting stored in the look-up table that is stored on the external memory.

In a variant of the above-explained embodiments, the respective trimming setting to be used—e.g. the number of resistors to be activated or to be deactivated—is not definitely predetermined by the data stored in the look-up table, but is only ascertained from these data by the trimming selection control means 205, e.g. by the use of appropriate linear interpolation methods, algorithmic calculating methods, etc.

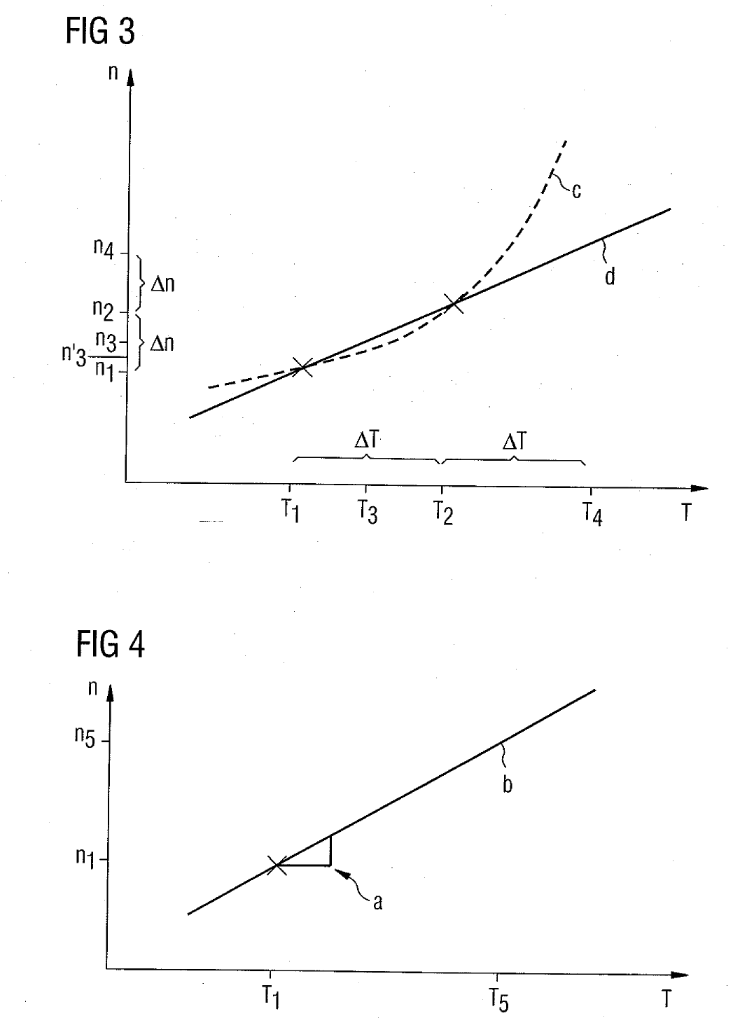

In the above-mentioned look-up table, for instance, only the respective number (n1, n2) of resistors to be activated or to be deactivated and to be used for a first and for a second temperature (T1, T2) may be stored (cf FIG. 3).

The number of resistors to be activated or to be deactivated (i.e. to be used and not to be used during regular operation of the semiconductor device for the generation of the corresponding reference voltage/reference current) for temperatures ranging between the first and second temperatures (T1, T2), or above or below these temperatures, respectively, is determined by the trimming selection control 205 by linear interpolation from the values stored in the look-up table.

For instance, in the case of a temperature (T3) that lies exactly between the first and second temperatures (T1, T2), a number (n3) of resistors that are to be activated or to be deactivated is used, which lies (exactly or as exactly as possible) between the number (n1) of resistors to be activated or to be deactivated at the first temperature (T1) and the number (n2) of resistors to be activated or to be deactivated at the second temperature (T2).

Furthermore, in the case of a temperature (T4) that lies by the difference ΔT between the first and second temperatures (T1, T2) above the second temperature (T2), a number (n4) of resistors to be activated or to be deactivated is used, which is by the difference Δn between the number (n1) of resistors to be activated or to be deactivated at the first temperature (T1) and the number (n2) of resistors to be activated or to be deactivated at the second temperature (T2) larger than the number (n2) of resistors to be activated or to be deactivated at the second temperature (T2).

In a further variant, only the number (n1) of resistors to be activated or to be deactivated and to be used for a first temperature (T1) may be stored in the above-mentioned look-up table, and a corresponding straight line gradient or direction value (a) (cf FIG. 4).

The number (e.g. n5) of resistors to be activated or to be deactivated (i.e. to be used and not to be used during regular operation of the semiconductor device for the generation of the corresponding reference voltage/reference current) and to be used for other temperatures (e.g. the temperature T5), is determined by the trimming selection control 205 by the temperature and resistor number value pair (T1; n1) stored in the look-up table and a straight line b which progresses, in a corresponding diagram that is, for instance, illustrated in FIG. 4, through a point defined by the temperature and resistor number value pair (T1; n1), and which has the gradient predetermined by the above-mentioned gradient value (a).

Correspondingly as explained above, the corresponding number of resistors of the above-mentioned set of resistors may, by the trimming selection control 205, depending on the respective result of the respective linear interpolation method, be placed in an “activated” state (i.e. be used during regular operation of the semiconductor device for the generation of the corresponding reference voltage/reference current), or be placed in a “deactivated” state (i.e. not be used during regular operation of the semiconductor device for the generation of the corresponding reference voltage/reference current).

Instead of the linear interpolation methods explained above by using FIGS. 3 and 4, appropriate algorithmic calculation methods may also be used for ascertaining the number of resistors of the above-mentioned set of resistors which are to be “activated” or to be “deactivated”.

Graphically, the ascertainment of the number of resistors of the above-mentioned set of resistors which are to be “activated” or to be “deactivated” is then—in corresponding temperature/resistor number diagrams—not based on corresponding straight lines (cf., for instance, the straight line d illustrated in FIG. 3), but on exponential curves (cf. the exponential curve c illustrated in dashes in FIG. 3).

For a temperature T3 there will then, as is illustrated in FIG. 3, e.g. not result, as in the above-mentioned linear interpolation method, a number n3 of resistors to be “activated” or to be “deactivated”, but a—deviating—number n3′ of resistors to be “activated” or to be “deactivated”.

For performing the algorithmic calculation methods, the number (nil, n2) of resistors to be activated or to be deactivated and to be used, for instance, for a first and for a second temperature (T1, T2) (or else for correspondingly more temperatures) may, again, be stored in the above-mentioned look-up table (correspondingly similar as illustrated in FIG. 3).

Alternatively, even if corresponding algorithmic calculation methods are used, only the respective number (n1) of resistors to be activated or to be deactivated and to be used for a first temperature (T1) may be stored in the look-up table, etc., (correspondingly similar as illustrated in FIG. 4).

For performing the above-mentioned algorithmic calculation methods, appropriate analog circuits may be used.

By using the above-mentioned algorithmic calculation methods—since a plurality of parameters (voltages, currents, etc.) depend on the temperature not in a linear, but in a logarithmic way—it may be achieved that the respectively ascertained trimming setting is better adapted to the respective temperature than in the above-mentioned linear interpolation methods.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed:

1. A method determining target values for a parameter of a semiconductor device to be trimmed, the method comprising:
determining a first target value for a parameter to be trimmed for a first temperature; and
determining a second target value differing from the first target value for the parameter to be trimmed for a second temperature differing from the first temperature.

2. The method of claim 1, wherein the step of determining the first target value for the parameter to be trimmed for the first temperature comprises:
performing a first semiconductor device test at the first temperature,
and wherein the step of determining the second target value for the parameter to be trimmed for the second temperature comprises:
performing the first semiconductor device test at the second temperature.

3. The method of claim 2, wherein the step of determining the first target value for the parameter to be trimmed for the first temperature comprises:
performing a second semiconductor device test differing from the first semiconductor device test at the first temperature,
and wherein the step of determining the second target value for the parameter to be trimmed for the second temperature comprises:
performing the second semiconductor device test at the second temperature.

4. The method of claim 1, further comprising:
determining a third target value differing from the first and second target values for the parameter to be trimmed for a third temperature differing from the first and second temperatures.

5. The method of claim 4, wherein the step of determining the third target value for the parameter to be trimmed for the third temperature, comprises:
performing the first semiconductor device test at the third temperature.

6. The method of claim 5, wherein the step of determining the third target value for the parameter to be trimmed for the third temperature further comprises:
performing the second semiconductor device test differing from the first semiconductor device test at the third temperature.

7. A method for trimming a semiconductor device, comprising:
trimming a parameter of a semiconductor device for a first temperature such that the parameter at the first temperature matches a first target value for the parameter to be trimmed which has been determined for the first temperature; and
trimming the parameter of the semiconductor device for a second temperature differing from the first temperature such that the parameter at the second temperature matches a second target value for the parameter to be trimmed which has been determined for the second temperature.

8. The method of claim 7, wherein the step of trimming the parameter for the first temperature comprises:
performing a first semiconductor device test at the first temperature,
and wherein the step of trimming the parameter for the second temperature comprises:
performing the first semiconductor device test at the second temperature.

9. The method of claim 8, wherein the step of trimming the parameter for the first temperature further comprises:
performing a second semiconductor device test differing from the first semiconductor device test at the first temperature,
and wherein the step of trimming the parameter for the second temperature further comprises:
performing the second semiconductor device test at the second temperature.

10. The method of claim 7, further comprising:
trimming the parameter of the semiconductor device for a third temperature differing from the first and second temperatures such that the parameter at the third temperature matches a third target value for the parameter to be trimmed which has been determined for the third temperature.

11. The method of claim 7, wherein the trimmed parameter is a reference voltage used on the semiconductor device.

12. The method of claim 7, wherein the trimmed parameter is a reference current used on the semiconductor device.

13. A method for operating a semiconductor device, comprising:
ascertaining a temperature assigned to the semiconductor device;
using a first trimming or a second trimming differing from the first trimming for a parameter of the semiconductor device, depending on the ascertained temperature.

14. The method of claim 13, further comprising reading out the first trimming or the second trimming to be used from a memory.

15. The method of claim 14, wherein the memory is provided on the semiconductor device.

16. The method of claim 14, wherein the memory is provided externally of the semiconductor device.

17. The method of claim 13, further comprising ascertaining the trimming to be used from data that are stored in a memory.

18. The method of claim 17, wherein a linear or an algorithmic calculation method is used for ascertaining the trimming.

19. The method of claim 17, wherein the memory is provided on the semiconductor device.

20. The method of claim 17, wherein the memory is provided externally of the semiconductor device.

21. A semiconductor device comprising:
a controller for activating a first trimming or a second trimming differing from the first trimming for a parameter of the semiconductor device, depending on a temperature assigned to the semiconductor device.

22. The semiconductor device of claim 21, further comprising a sensor for ascertaining the temperature assigned to the semiconductor device.

23. The semiconductor device of claim 21, wherein the semiconductor device includes a memory device.
